(19) United States
(12) Patent Application Publication
(10) Pub. No.: US 2025/0390619 A1
(43) Pub. Date: Dec. 25, 2025

(54) AUTO LAYOUT INFERENCE ENGINE

(71) Applicant: FIGMA, INC., San Francisco, CA (US)

(72) Inventors: Yi Tang Jackie CHUI, Bellevue, WA (US); Shirley MIAO, Brooklyn, NY (US); Tom GIANNATTASIO, Pittsford, NY (US); Ahmed ABDALLA, New York, NY (US); Michael BULLINGTON, New York, NY (US)

(21) Appl. No.: 19/248,337

(22) Filed: Jun. 24, 2025

Related U.S. Application Data
(60) Provisional application No. 63/663,578, filed on Jun. 24, 2024.

(51) Int. Cl. G06F 30/12

(52) U.S. Cl. CPC G06F 30/12

(57) ABSTRACT

A computing system builds a graph of nodes representing design elements within a design interface having a flat structure, wherein edge weights between adjacent nodes in the graph of nodes include (1) an alignment hit count and (2) a distance measurement between the adjacent nodes. The system iteratively merges the nodes in the graph of nodes based on the edge weights, and converts, within the design interface, the flat structure into a responsive structure, with positions and sizes of the design elements unchanged, based on merging the nodes.

### CROSS-REFERENCE TO RELATED APPLICATIONS

This application claims the priority benefit of United States provisional patent application titled, “AUTO LAYOUT INFERENCE ENGINE,” filed Jun. 24, 2024, and having Ser. No. 63/663,578. The subject matter of this related application is hereby incorporated herein by reference.

### TECHNICAL FIELD

Examples described herein relate to a system and method for adding responsive structure to a flat graphical design layout.

### BACKGROUND

Software design tools allow designers to blend functional aspects of a program with aesthetics to create a collection of pages which form the user interface of an application. Graphic designers of applications often face several challenges, including maintaining a balance between aesthetics and functionality, ensuring the user interface (UI) is intuitive and user-friendly, and achieving consistency across different devices and screen sizes. They must also stay updated with rapidly evolving design trends and technological advancements, which can require continuous learning and adaptation. Collaboration with developers can pose difficulties, especially when translating visual concepts into functional code. Additionally, designers need to consider accessibility standards to ensure that applications are usable by individuals with various disabilities, further complicating the design process.

### BRIEF DESCRIPTION OF THE DRAWINGS

FIG. 1A illustrates an interactive graphic design system for a computing device of a user, according to one or more examples.

FIG. 1B illustrates a network computing system to implement an interactive graphic design system on a user computing device, according to one or more examples.

FIG. 1C illustrates a network computing system to implement an interactive graphic design system for multiple users in a collaborative network platform, according to one or more examples.

FIG. 2 illustrates an example flat design converted into a responsive design, including an example XML output, through an auto layout inference engine.

FIG. 3 illustrates an example visual graph representation of a design with nodes and edge weights shown.

FIG. 4 illustrates an example of ray casting to determine an alignment hit count between nodes in a design.

FIG. 5 is an example flow chart of a method of reducing a graph of design element nodes as part of converting a flat design to a responsive design through an auto layout inference engine.

FIG. 6 illustrates a network computer system on which one or more embodiments can be implemented.

FIG. 7 illustrates a user computing device for use with one or more examples, as described.

### DETAILED DESCRIPTION

An auto layout inference engine turns a visual ideal design into a responsively ideal design in an automated way. The system enables a designer to create a flat design and easily turn it into a responsive design to express how it should behave in a production environment. As used herein, a “responsive design” or “responsive structure” is one that progressively changes its layout when viewed across multiple devices as well as screen sizes by scaling its content and elements accordingly. For example, a responsive design can adapt and fit as screen sizes change to accommodate displayed information, such as by decreasing the spacing, changing a layout from horizontal to vertical, and changing grid sizes to maintain a comparable, consistent experience across contexts.

Auto layout is a powerful tool that enables designers to create dynamic and responsive designs more efficiently within an interactive graphic design system. It allows elements within a frame to automatically adjust their size and position based on the content and constraints set by the designer. With auto layout, components such as buttons, lists, and grids can adapt to changes in text length, screen size, or the addition of new elements, maintaining consistent spacing and alignment. This feature simplifies the creation of flexible and scalable UI designs, making it easier to manage and update layouts without manual adjustments. It can support various alignment and spacing options, padding controls, and resizing behaviors, streamlining the design process and ensuring a cohesive and responsive design system.

However, even for an experienced designer, converting a flat layout into a responsive one, such as one taking advantage of an auto layout feature, can be prohibitively time consuming. The designer would need to manually break the design apart, identify composite stacks of individual components, and put the design back together with auto layout applied. An auto layout inference engine solves this problem by automating the process.

In some examples, an auto layout inference engine builds a graph of nodes representing design elements within a design interface having a flat structure, wherein edge weights between adjacent nodes in the graph of nodes include (1) an alignment hit count and (2) a distance measurement between the adjacent nodes. The system iteratively merges the nodes in the graph of nodes based on the edge weights, and converts, within the design interface, the flat structure into a responsive structure, with positions and sizes of the design elements unchanged, based on merging the nodes.

In some examples, the system determines the alignment hit count between adjacent nodes in the graph by (1) casting rays from each corner of the adjacent nodes in both X and Y directions, and (2) counting the number of times a ray from one node intersects the other node.

In some examples, iteratively merging the nodes in the graph of nodes based on the edge weights comprises (a) selecting a pair of adjacent nodes with a predetermined minimum alignment hit count and a least distance measurement between them; (b) combining the pair of adjacent nodes into a new node in the graph of nodes; (c) removing the pair of adjacent nodes from the graph of nodes; and (d) repeating (a)-(c) until a single node remains.

In some examples, the flat structure is converted into the responsive structure by inserting vertical stacks and/or horizontal stacks as ancestors of the design elements upon combining the pair of adjacent nodes into the new node. Alignments and responsiveness features for each of the vertical and horizontal stacks can also be set.

In some examples, the distance measurement between the adjacent nodes is the number of pixels between the closest sides of the adjacent nodes.

One or more aspects described herein provide that methods, techniques and actions performed by a computing device are performed programmatically, or as a computer-implemented method. Programmatically means through the use of code, or computer-executable instructions. A programmatically performed step may or may not be automatic.

One or more aspects described herein may be implemented using programmatic modules or components. A programmatic module or component may include a program, a subroutine, a portion of a program, a software component, or a hardware component capable of performing one or more stated tasks or functions. In addition, a module or component can exist on a hardware component independently of other modules or components. Alternatively, a module or component can be a shared element or process of other modules, programs, or machines.

Furthermore, one or more aspects described herein may be implemented through the use of instructions that are executable by one or more processors. These instructions may be stored on a computer-readable medium. Machines shown or described with figures below provide examples of processing resources and computer-readable media on which instructions for implementing some aspects can be stored and/or executed. In particular, the numerous machines shown or described include processors and various forms of memory for storing data and instructions. Examples of computer-readable media include permanent memory storage devices, such as hard drives on personal computers or servers. Other examples of computer storage media include portable storage units, such as CD or DVD units, flash or solid-state memory (such as carried on many cell phones and consumer electronic devices), and magnetic memory. Computers, terminals, and network-enabled devices (e.g., mobile devices such as cell phones) are all examples of machines and devices that utilize processors, memory, and instructions stored on computer-readable media.

Alternatively, one or more examples described herein may be implemented through the use of dedicated hardware logic circuits that are comprised of an interconnection of logic gates. Such circuits are typically designed using a hardware description language (HDL), such as Verilog and VHDL. These languages contain instructions that ultimately define the layout of the circuit. However, once the circuit is fabricated, there are no instructions, and processing is performed by interconnected gates.

### System Description

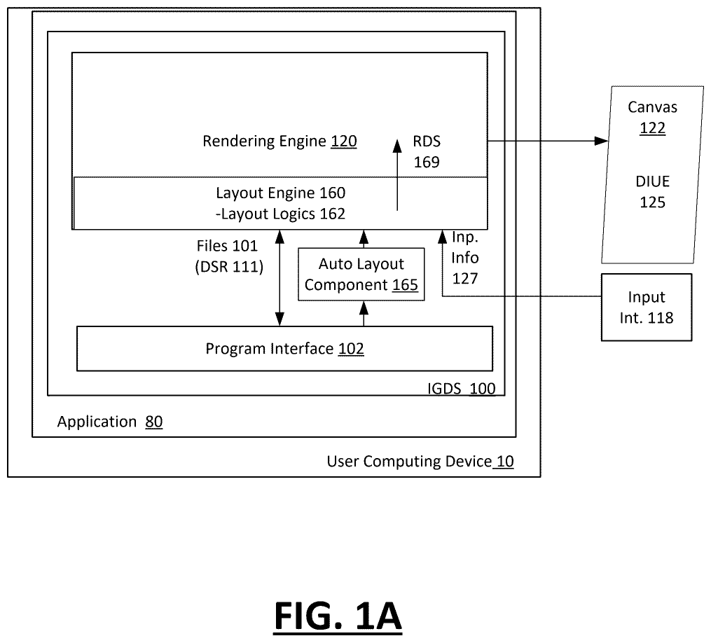

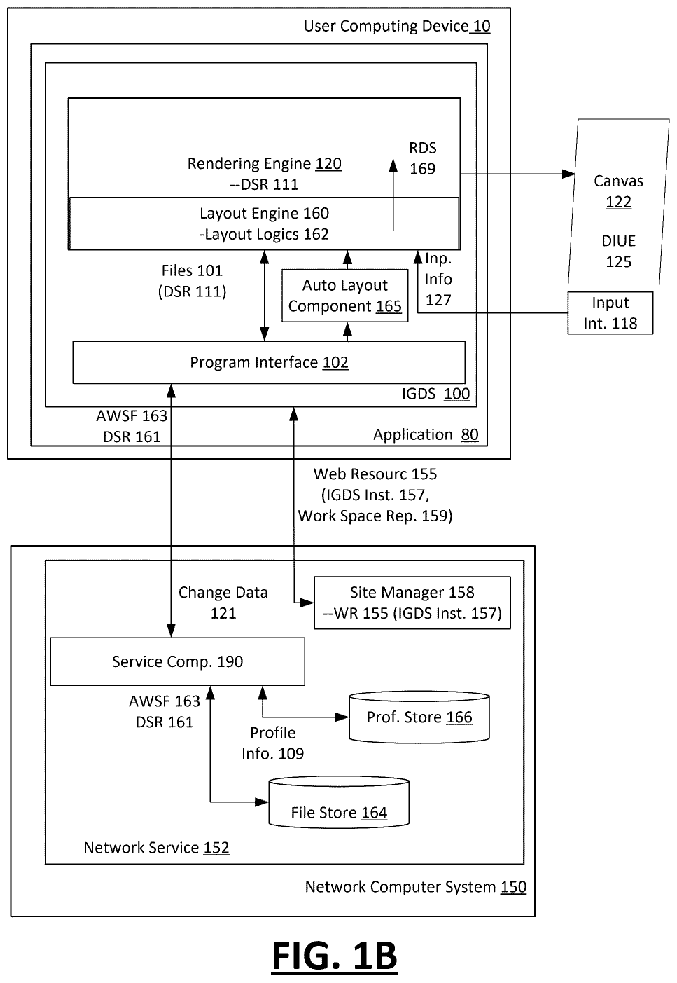

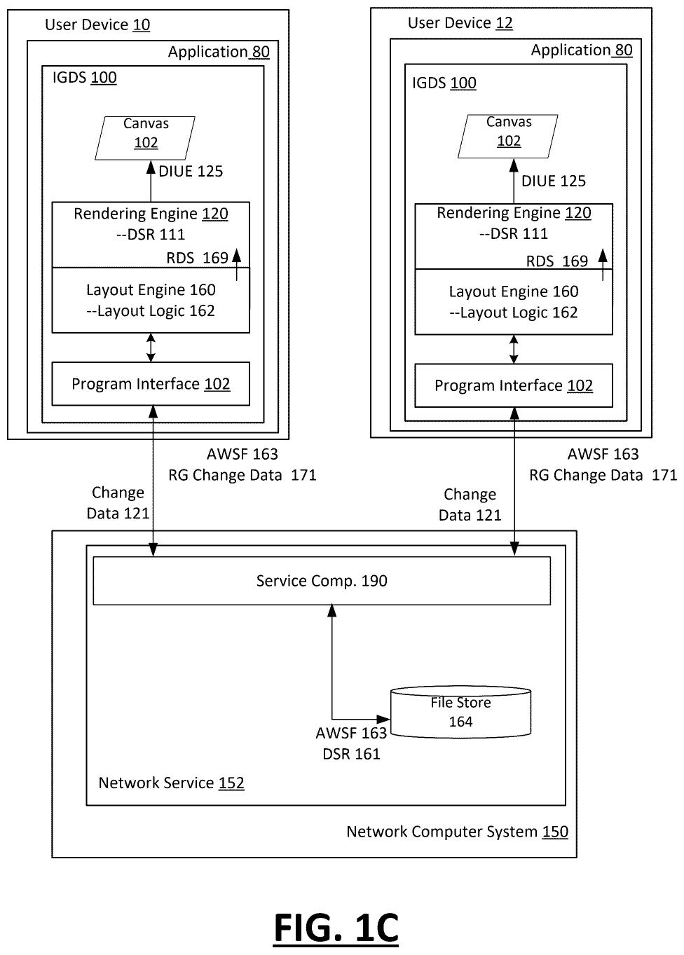

FIG. 1A illustrates an interactive graphic design system for a computing device of a user, according to one or more examples. An interactive graphic design system (“IGDS”) 100 can be implemented in any one of multiple different computing environments. For example, in some variations, the IGDS 100 can be implemented as a client-side application that executes on the user computing device 10 to provide functionality as described with various examples. In other examples, such as described below, the IGDS 100 can be implemented through use of a web-based application 80. As an addition or alternative, the IGDS 100 can be implemented as a distributed system, such that processes described with various examples execute on a network computer (e.g., server) and on the user device 10.

According to examples, the IGDS 100 can be implemented on a user computing device 10 to enable a corresponding user to design various types of interfaces using graphical elements. The IGDS 100 can include processes that execute as or through a web-based application 80 that is installed on the computing device 10. As described by various examples, web-based application 80 can execute scripts, code and/or other logic (the “programmatic components”) to implement functionality of the IGDS 100. Additionally, in some variations, the IGDS 100 can be implemented as part of a network service, where web-based application 80 communicates with one or more remote computers (e.g., server used for a network service) to executes processes of the IGDS 100.

In some examples, web-based application 80 retrieves some or all of the programmatic resources for implementing the IGDS 100 from a network site. As an addition or alternative, web-based application 80 can retrieve some or all of the programmatic resources from a local source (e.g., local memory residing with the computing device 10). The web-based application 80 may also access various types of data sets in providing the IGDS 100. The data sets can correspond to files and libraries, which can be stored remotely (e.g., on a server, in association with an account) or locally.

In examples, the web-based application 80 can correspond to a commercially available browser, such as GOOGLE CHROME (developed by GOOGLE, INC.), SAFARI (developed by APPLE, INC.), and INTERNET EXPLORER (developed by the MICROSOFT CORPORATION). In such examples, the processes of the IGDS 100 can be implemented as scripts and/or other embedded code which web-based application 80 downloads from a network site. For example, the web-based application 80 can execute code that is embedded within a webpage to implement processes of the IGDS 100. The web-based application 80 can also execute the scripts to retrieve other scripts and programmatic resources (e.g., libraries) from the network site and/or other local or remote locations. By way of example, the web-based application 80 may execute JAVASCRIPT embedded in an HTML resource (e.g., web-page structured in accordance with HTML 5.0 or other versions, as provided under standards published by W3C or WHATWG consortiums). In some examples, the rendering engine 120, layout engine 160 and/or other components may utilize graphics processing unit (GPU) accelerated logic, such as provided through WebGL (Web Graphics Library) programs which execute Graphics Library Shader Language (GLSL) programs that execute on GPUs.

According to examples, user of computing device 10 operates web-based application 80 to access a network site, where programmatic resources are retrieved and executed to implement the IGDS 100. In this way, the user may initiate a session to implement the IGDS 100 for purpose of creating and/or editing a design interface. In examples, the IGDS 100 includes a program interface 102, an input interface 118, a rendering engine 120 and a layout engine 160. The program interface 102 can include one or more processes which execute to access and retrieve programmatic resources from local and/or remote sources.

In an implementation, the program interface 102 can generate, for example, a canvas 122, using programmatic resources which are associated with web-based application 80 (e.g., HTML 5.0 canvas). As an addition or variation, the program interface 102 can trigger or otherwise cause the canvas 122 to be generated using programmatic resources and data sets (e.g., canvas parameters) which are retrieved from local (e.g., memory) or remote sources (e.g., from network service).

The program interface 102 may also retrieve programmatic resources that include an application framework for use with canvas 122. The application framework can include data sets which define or configure, for example, a set of interactive graphic tools that integrate with the canvas 122 and which comprise the input interface 118, to enable the user to provide input for creating and/or editing a design interface.

According to some examples, the input interface 118 can be implemented as a functional layer that is integrated with the canvas 122 to detect and interpret user input. The input interface 118 can, for example, use a reference of the canvas 122 to identify a screen location of a user input (e.g., ‘click’). Additionally, the input interface 118 can interpret an input action of the user based on the location of the detected input (e.g., whether the position of the input indicates selection of a tool, an object rendered on the canvas, or region of the canvas), the frequency of the detected input in a given time period (e.g., double-click), and/or the start and end position of an input or series of inputs (e.g., start and end position of a click and drag), as well as various other input types which the user can specify (e.g., right-click, screen-tap, etc.) through one or more input devices. In this manner, the input interface 118 can interpret, for example, a series of inputs as a design tool selection (e.g., shape selection based on location of input), as well as inputs to define attributes (e.g., dimensions) of a selected shape.

Additionally, the program interface 102 can be used to retrieve, from local or remote sources, programmatic resources and data sets which include files 101 which comprise an active workspace for the user. The retrieved data sets can include one or more pages that include design elements which collectively form a design interface, or a design interface that is in progress. Each file 101 can include one or multiple data structure representations 111 which collectively define the design interface. The files 101 may also include additional data sets which are associated with the active workspace. For example, as described with some examples, the individual pages of the active workspace may be associated with a set of constraints 145. As an additional example, the program interface 102 can retrieve (e.g., from network service 152 (see FIG. 1B), from local memory, etc.) one or more types of profile information 109, such as user profile information which can identify past activities of the user of the computing device 10 when utilizing the IGDS 100. The profile information 109 can identify, for example, input types (or actions) of the user with respect to the page(s) of the active workspace, or more generally, input actions of the user in a prior time interval. In some variations, the profile information 109 can also identify historical or contextual information about individual design interfaces, as represented by corresponding data structure representations 111. As another example, the files 101 can include layout logic 162 for implementing layout configurations amongst object groupings. For example, the files 101 can include a collection of layout logic a user can select and deploy for a given design under edit. Additionally, the files 101 can include data sets which represent a deployed layout logic 162. Such data sets can further include data that links or otherwise associates the particular layout logic 162 with a particular object grouping, as well as data that identifies settings, values and other selections of the user with respect to the manner in which the layout logic 162 is implemented on the design under edit.

In examples, the rendering engine 120 uses the data structure representations 111 to render a corresponding DUE 125 on the canvas 122, where the DUE 125 reflects graphic elements and their respective attributes as provided with the individual pages of the files 101. The user can edit the DUE 125 using the input interface 118. Alternatively, the rendering engine 120 can generate a blank page for the canvas 122, and the user can use the input interface 118 to generate the DUE 125. As rendered, the DUE 125 can include graphic elements such as a background and/or a set of objects (e.g., shapes, text, images, programmatic elements), as well as attributes of the individual graphic elements. Each attribute of a graphic element can include an attribute type and an attribute value. For an object, the types of attributes include, shape, dimension (or size), layer, type, color, line thickness, text size, text color, font, and/or other visual characteristics. Depending on implementation, the attributes reflect properties of two- or three-dimensional designs. In this way, attribute values of individual objects can define, for example, visual characteristics of size, color, positioning, layering, and content, for elements that are rendered as part of the DUE 125.

In examples, individual design elements may also be defined in accordance with a desired run-time behavior. By way of example, some objects can be defined to have run-time behaviors that are either static or dynamic. The attributes of dynamic objects may change in response to predefined run-time events generated by the underlying application that is to incorporate the DUE 125. Additionally, some objects may be associated with logic that defines the object as being a trigger for rendering or changing other objects, such as through implementation of a sequence or workflow. Still further, other objects may be associated with logic that provides the design elements to be conditional as to when they are rendered and/or their respective configuration or appearance when rendered. Still further, objects may also be defined to be interactive, where one or more attributes of the object may change based on user-input during the run-time of the application.

The input interface 118 can receive and process at least some user inputs to determine input information 127, where the input information 127 indicates (i) an input action type (e.g., shape selection, object selection, object sizing input, object positioning input, color selection), (ii) an object that is directly indicated by the input action (e.g., object being resized), (iii) a desired attribute that is to be altered by the input action, and/or (iv) a desired value for the attribute being altered. The rendering engine 120 can receive the input information 127, and the rendering engine 120 can implement changes indicated by the input information 127 to update the DUE 125. When changes are implemented to the DUE 125, the changes can also be reflected in the accompanying data structure representations 111 for the DUE 125.

### Layout Engine

In examples, the rendering engine 120 executes in conjunction with a layout engine 160. Among other functions, layout engine 160 operates to enable the user to (i) enable a user to select a layout logic 162 from a collection, (ii) configure the layout logic to selectively deploy and be linked with a selected object grouping, and (iii) implement a layout configuration that is defined by the select layout logic 162 for the linked object grouping while the linked object grouping is being manipulated (e.g., resized or repositioned) by user input. When a particular layout logic 162 is selected and linked to a rendered object grouping, the layout engine 160 can further operate to detect and receive input information 127 for user inputs that are directed to the linked object grouping.

According to some examples, the layout engine 160 can process the input information 127, which may indicate, for example, a resizing or repositioning of one or more objects of the object grouping, using the select layout logic 162 that is linked to that object grouping. The layout engine 160 can execute the selected layout logic 162 to determine, for example, a resizing or repositioning of individual objects of the object grouping for purpose of maintaining a layout configuration that is defined by the linked layout logic 162 while carrying out the corresponding input action of the user. The layout engine 160 can further generate a result data set 169 from implementing the linked layout logic 162. The result data set 169 can include position information, boundary information (e.g., position information that identifies one or more boundaries of an object or object set) and/or dimensional information (e.g., one or more dimensions of a frame of an object or object set) for individual objects of the linked object grouping. The result data set 169 can represent a change to the object grouping as a result of the user input (e.g., to resize or reposition object(s) of the object grouping), as well as the implementation of the predefined layout configuration. The rendering engine 120 can process the result data set 169 to reflect the changes to the object grouping, stemming from the user input and the implementation of the predefined layout configuration of the selected layout logic 162.

Each layout logic 162 can include an instruction set and data that collectively rules and settings for implementing a predefined layout configuration amongst object grouping. By way of example, the layout logic 162 can define a layout configuration that identifies a relative positioning, dimensional relationship and/or spacing as between or amongst individual objects of a linked object grouping.

As described in greater detail, a user can provide selection input to select one or more layout logics 162 of a layout logic collection for deployment with a select grouping of objects that are rendered as part of the DUE 125. In examples, the layout engine 120 can associate a selected layout logic 162 with a particular object grouping, such as a parent child grouping. Once the selected layout logic 162 is associated with a particular object grouping, the layout engine 160 can implement the predefined layout configuration as a response to one or more predefined triggers of the select layout logic 162.

As further described, the layout configurations which are implemented by the layout engine 160 can be instant and responsive to changes made to other objects of the select object grouping. In examples, the layout engine 160 can execute the selected layout logic 162 to (i) detect user input to resize or reposition a specific object of the object grouping, (ii) calculate changes to make in size or position to one or more objects in order to implement the layout configuration of the selected layout logic 162, (iii) communicate the changes (e.g., object positioning data, object border data) to the rendering engine 120 for rendering, along with a change resulting from user input. In examples, the layout engine 160 can execute with rendering engine 120 to fluidly, and in-real time, reflect changes to an object grouping as a result of user input to one or more of the objects of the object grouping. For example, the operations of detecting, calculating and rendering can be done at a speed that is approximately equal to 0.0167 seconds, so that the changes caused by user input and implementation of the layout configuration appear fluid and instant to the user operating a 60 HZ monitor.

The layout engine 160 can execute select layout logic 162 to automatically implement one or more layout configurations amongst object groupings that are arranged, or otherwise linked, to have a parent/child relationship. For example, a user can interact with DUE 125 to parent an object to another object (e.g., select and drag one object over another object). In parent/child object groupings, the child object(s) may be positioned within a frame of the parent object. The layout engine 160 can execute select layout logics 160 to automatically resize or reposition one or more objects of a respective linked parent child grouping, where the resizing/repositioning is based on resizing or repositioning changes of other objects of the parent child grouping.

By way of examples, layout engine 160 can execute a first layout logic 162 to implement a first layout configuration in which a dimension of a parent object is resized to minimize a difference between dimension(s) of the parent and child object(s) (e.g., parent object ‘hugs’ child objects). Additionally, the layout engine 160 can execute a second layout logic to implement a second layout configuration in which a dimension of one or more child object(s) are resized to minimize a difference between the dimensions of the parent and child object(s) (e.g., by having child object(s) ‘fill’ the parent object). As an addition or variation, the layout engine 160 can execute additional layout logics 162 that implement one or more spacing configurations as between select objects of the object groupings (e.g., as between child and parent objects, and/or as between child objects).

As another addition or variation, the layout engine 160 can execute layout logic 162 to implement configurations for wrapping, reverse wrapping or no wrapping with respect to child objects that are added or removed from a parent object, so as increase or decrease a collective size of the child objects within a parent object. In a wrapping configuration, the addition of child objects can cause a dimension of a parent object to increase in a particular direction (e.g., downward) to accommodate the addition, and an orientation of the collective child objects expanding (e.g., by addition of child objects) can reflect that direction. Similarly, in reverse wrapping, the reduction of child objects can cause a dimension of a parent object to decrease in a particular direction to accommodate removal of an object from the parent object, and a dimension of the collective child objects can similarly reduce in that direction.

For an associated object grouping, the layout logic 162 can define (i) a target object set of one or more target objects, (ii) as associated object set of one or more associated objects, and (iii) rules and/or settings that define a layout configuration for the target object(s). The target object set can correspond to the object(s) that are to be subject to the layout configuration, as implemented by the layout engine 160. The associated object set can include objects of the object grouping that can trigger the layout engine 160 to implement the select layout configuration on the target object set. In defining the associated object set, the select layout logic 162 can also define one or more attributes of the associated object set which can trigger the layout engine 160 to implement the respective predefined layout configuration on the respective target object set. As an addition or variation, the select layout logic 162 can define a change to a dimensional attribute or position of the associated object set, for purpose of defining when changed to the dimensional attribute or position of the associated object triggers the layout engine 160 to implement the predefined layout configuration on the target object set. By way of an example, the layout logic 162 can provide that any change to the dimension of the associated object triggers implementation of the predefined layout configuration for the target object set. As another example, the layout logic 162 can provide that any change to a position of a portion of an associated object (e.g., position or coordinates of an object's boundary) triggers implementation of the predefined layout configuration for the target object set. In this way, the layout logic 162 can be responsive to one or more dimensional or positional changes of an associated object set.

Moreover, in some examples, users can specify that the application of the layout logic 162 is specific to a particular direction or orientation (e.g., horizontal, vertical). If a layout configuration is specified to be specific to a particular direction or orientation, the layout engine configures implementation of the layout configuration to be specific to the specified direction. Further, the layout logic 162 is only responsive to resizing or repositioning of the associated object set in the specified direction.

Additionally, in some examples, the user can specify thresholds that define a magnitude or amount of change to an associate object set that is resized or repositioned, before the selected layout logic 162 implements a predefined layout configuration.

According to some examples, layout engine 160 can implement operations to determine, in real-time, coordinates of a portion of an associated object (e.g., a left, right, top or bottom boundary of the associate object's frame, a corner of the associate object's frame, etc.) that is being repositioned, as part of a user input operation to resize or move the associated object or otherwise alter an associated object set. The layout engine 160 can utilize the determined coordinates of the portion of the associated object that is being manipulated as input for the layout configuration of the target object set. In examples, the layout engine 160 can obtain and act on the coordinate information obtained for the parent object, so as to instantly implement the layout configuration on the target object set.

By way of examples, the select layout logics 162 that can be deployed for use in association with a parent child object grouping can include fill layout logic, hug layout logic, and one or more spacing layout logics. As described elsewhere, the fill layout logic can implement a fill layout configuration where one or more child objects are automatically resized and/or repositioned, as a response to input that resizes or repositions the parent object. In variations, the fill layout logic can be configured to apply changes to the target object set (child object(s)) in a particular direction (e.g., horizontal or vertical directions), as a response to changes to the associated object set (parent object) which are in the same particular direction.

The hug layout logic can implement a fill layout configuration where a parent object is automatically resized and/or repositioned. A trigger for the hug layout logic can include input that resizes or repositions individual child objects or the respective child objects collectively. In variations, the hug layout logic can also be configured to apply changes to the target object set (parent) in a particular direction (e.g., horizontal or vertical directions), as a response to changes to the associated object set (child object(s)) which are in the same particular direction.

As an additional example, an even spacing layout logic can implement a spacing configuration amongst child objects of a parent/object grouping, where the child objects are maintained in a configuration where they are evenly spaced from one another. The target object set of the even spacing layout logic can correspond to all child objects of a parent/child object grouping, and the associated object set of the even spacing layout logic can correspond to the parent object and all of the child objects of the parent/child object grouping.

When the even spacing layout logic is deployed with a parent/child object grouping, the layout engine 160 can respond to the parent object being resized by equally resizing each child object of the parent object, and further by repositioning each child object (as resized) to be spaced from its respective neighbor child object(s) by the same amount. The layout engine 160 can respond to the parent object being repositioned in similar fashion—by repositioning all of the child objects to maintain the even spacing between the child objects. In some implementations, if an additional child object is added to the parent object, or if one or more of the child objects are resized, the layout engine 160 automatically repositions each of the child objects to maintain the equal spacing amongst all adjacent pairs of child objects. Additionally, in variations, the even spacing layout logic can be configured to implement the spacing configuration to the target object set (all of the child objects) in a particular direction (e.g., horizontal or vertical directions), as a response to changes to the associated object set (child object, parent object) that are in the same particular direction.

As another example, a fixed spacing layout logic can implement a fixed spacing configuration amongst adjacent objects of an object grouping. In a parent/child object grouping, the fixed spacing configuration can specify a fixed spacing between, for example, a boundary of a child object (e.g., a boundary corresponding to a portion of a frame of the child object) and a boundary of a parent object (e.g., a boundary corresponding to a portion of a frame of the parent object). Thus, for example, input by a user to reposition or resize a parent object can cause the layout engine 160 to reposition the child object so that the fixed spacing between the respective boundaries of the parent and child objects is maintained.

In examples, a user can access features provided by an auto layout component 165 through the program interface 102. Among other functions, auto layout component 165 operates to enable the user to convert a flat design (e.g., a design with few, if any, layout logics 162 applied to the design elements) into a responsively ideal design in an automated way. For example, the user can select an “apply auto layout” option through the program interface 102, and the auto layout component 165 can alter the DIUE 125 to create new design elements, such as horizontal and vertical stacks, and to apply layout logics 162 to the design elements, resulting in a responsive design.

### Network Computing System to Implement IGDS

FIG. 1B illustrates a network computing system to implement an interactive graphic design system on a user computing device, according to one or more examples. A network computing system such as described with an example of FIG. 1B can be implemented using one or more servers which communicate with user computing devices over one or more networks.

In an example of FIG. 1B, the network computing system 150 performs operations to enable the IGDS 100 to be implemented on the user computing device 10. In variations, the network computing system 150 provides a network service 152 to support the use of the IGDS 100 by user computing devices that utilize browsers or other web-based applications. The network computing system 150 can include a site manager 158 to manage a website where a set of web-resources 155 (e.g., web page) are made available for site visitors. The web-resources 155 can include instructions, such as scripts or other logic (“IGDS instructions 157”), which are executable by browsers or web components of user computing devices.

In some variations, once the computing device 10 accesses and downloads the web-resources 155, web-based application 80 executes the IGDS instructions 157 to implement functionality such as described with some examples of FIG. 1A. For example, the IGDS instructions 157 can be executed by web-based application 80 to initiate the program interface 102 on the user computing device 10. The initiation of the program interface 102 may coincide with the establishment of, for example, a web-socket connection between the program interface 102 and a service component 190 of the network computing system 150.

In some examples, the web-resources 155 includes logic which web-based application 80 executes to initiate one or more processes of the program interface 102, causing the IGDS 100 to retrieve additional programmatic resources and data sets for implementing functionality as described by examples. The web resources 155 can, for example, embed logic (e.g., JAVASCRIPT code), including GPU accelerated logic, in an HTLM page for download by computing devices of users. The program interface 102 can be triggered to retrieve additional programmatic resources and data sets from, for example, the network service 152, and/or from local resources of the computing device 10, in order to implement the IGDS 100. For example, some of the components of the IGDS 100 can be implemented through web-pages that can be downloaded onto the computing device 10 after authentication is performed, and/or once the user performs additional actions (e.g., download one or more pages of the workspace associated with the account identifier). Accordingly, in examples as described, the network computing system 150 can communicate the IGDS instructions 157 to the computing device 10 through a combination of network communications, including through downloading activity of web-based application 80, where the IGDS instructions 157 are received and executed by web-based application 80.

The computing device 10 can use web-based application 80 to access a website of the network service 152 to download the webpage or web resource. Upon accessing the website, web-based application 80 can automatically (e.g., through saved credentials) or through manual input, communicate an account identifier to the service component 190. In some examples, web-based application 80 can also communicate one or more additional identifiers that correlate to a user identifier.

Additionally, in some examples, the service component 190 can use the user or account identifier of the user identifier to retrieve profile information 109 from a user profile store 166. As an addition or variation, profile information 109 for the user can be determined and stored locally on the user's computing device 10. As described with other examples, the user profile information can be used to infer an outcome of an input action, based on the inputs of the user with respect to the DUE 125 (such as detected by the input interface 118). For example, the profile information 109 can be communicated to the IGDS 100, where the profile information 109 can be used to implement and develop the predictive logic 134.

The service component 190 can also retrieve the files of an active workspace (“active workspace files 163”) that are linked to the user account or identifier from a file store 164. The profile store 166 can also identify the workspace that is identified with the account and/or user, and the file store 164 can store the data sets that comprise the workspace. The data sets stored with the file store 164 can include, for example, the pages of a workspace, data sets that identify constraints for an active set of workspace files, and one or more data structure representations 161 for the design under edit which is renderable from the respective active workspace files.

Additionally, in examples, the service component 190 provides a representation 159 of the workspace associated with the user to the web-based application 80, where the representation identifies, for examples, individual files associated with the user and/or user account. The workspace representation 159 can also identify a set of files, where each file includes one or multiple pages, and each page including objects that are part of a design interface.

On the user device 10, the user can view the workspace representation through web-based application 80, and the user can elect to open a file of the workspace through web-based application 80. In examples, upon the user electing to open one of the active workspace files 163, web-based application 80 initiates the canvas 122. For example, the IGDS 100 can initiate an HTML 5.0 canvas as a component of web-based application 80, and the rendering engine 120 can access one or more data structures representations 111 of a design interface under edit, to render the corresponding DUE 125 on the canvas 122.

The service component 190 may also determine, based on the user credentials, a permission setting or role of the user in connection with the account identifier. The permission settings or role of the user can determine, for example, the files which can be accessed by the user. In some examples, the implementation of the rendering engine 120 on the computing device 10 can be configured based at least in part on the role or setting of the user.

In examples, the changes implemented by the rendering engine 120 to the DUE 125 can also be recorded with the respective data structure representations 111, as stored on the computing device 10. As described with some examples, the rendering engine 120 can implement changes reflected by user information 127, as well as changes represented by the result data set 169, as generated by the layout engine 160 implementing one or more select layout logic 162. The layout engine 160 can determine the result data set 169 for objects of an object grouping which is linked to a particular layout logic 162, when one or more of the objects are resized or reshaped by user input.

The program interface 102 can repeatedly, or continuously stream change data 121 to the service component 190, wherein the updates reflect edits as they are made to the DUE 125 and to the data structure representation 111 to reflect changes made by the user to the DUE 125 and to the local data structure representations 111 of the DUE 125. The service component 190 can receive the change data 121, which in turn can be used to implement changes to the network-side data structure representations 161. In this way, the network-side data structure representations 161 for the active workspace files 163 can mirror (or be synchronized with) the local data structure representations 111 on the user computing device 10. When the rendering engine 120 implements changes to the DUE 125 on the user device 10, the changes can be recorded or otherwise implemented with the local data structure representations 111, and the program interface 102 can stream the changes as change data 121 to the service component 190 in order to synchronize the local and network-side representations 111, 161 of the DUE 125. This process can be performed repeatedly or continuously, so that the local and network-side representations 111, 161 of the DUE 125 remain synchronized.

Additionally, the program interface 102 can record a selected layout logic 162 being applied to a particular object grouping. The active workspace files 163, for example, can include instructions and data (e.g., a file) for a selected layout logic 162. Additionally, the local data structure representations 111 can identify the portion of the DUE 125 for which input information 127 is to be handled by the layout engine 160.

### Collaborative Network Platform

FIG. 1C illustrates a network computing system to implement an interactive graphic design system for multiple users in a collaborative network platform, according to one or more examples. In an example of FIG. 1C, a collaborative network platform is implemented by the network computing system 150, which communicates with multiple user computing devices 10, 12 over one or more networks (e.g., World Wide Web) to implement the IGDS 100 on each computing device. While FIG. 1C illustrates an example in which two users utilize the collaborative network platform, examples as described allow for the network computing system 150 to enable collaboration on design interfaces amongst a larger group of users.

With respect to FIG. 1C, the user computing devices 10, 12 can be assumed as being operated by users that are associated with a common account, with each user computing device 10, 12 implementing a corresponding IGDS 100 to access the same workspace during respective sessions that overlap with one another. Accordingly, each of the user computing devices 10, 12 may access the same set of active workspace files 163 at the same time, with the respective program interface 102 of the IGDS 100 on each user computing device 10, 12 operating to establish a corresponding communication channel (e.g., web socket connection) with the service component 190.

In examples, the service component 190 can communicate a copy of the active workspace files 163 to each user computing device 10, 12, such that the computing devices 10, 12 render the DUE 125 of the active workspace files 163 at the same time. Additionally, each of the computing devices 10, 12 can maintain a local data structure representation 111 of the respective DUE 125, as determined from the active workspace files 163. The service component 190 can also maintain a network-side data structure representation 161 obtained from the files of the active workspace 163, and coinciding with the local data structure representations 111 on each of the computing devices 10, 12.

The network computing system 150 can continuously synchronize the active workspace files 163 on each of the user computing devices. In particular, changes made by users to the DUE 125 on one computing device 10, 12 may be immediately reflected on the DUE 125 rendered on the other user computing device 10, 12. By way of example, the user of computing devices 10 can make a change to the respective DUE 125, and the respective rendering engine 120 can implement an update that is reflected in the local copy of the data structure representation 111. Additionally, as described with other examples, the layout engine 160 can execute selected layout logic 162 for linked object groupings of the DUE 125, and the layout engine 160 can communicate the result data set 169 to the rendering engine 120 for implementing updates to the object grouping of the DUE 125. From the computing device 10, the program interface 102 of the IGDS 100 can stream change data 121, reflecting the change of the user input, to the service component 190. The service component 190 processes the change data 121 of the user computing device. The service component 190 can use the change data 121 to make a corresponding change to the network-side data structure representation 161. The service component 190 can also stream remotely-generated change data 171 (which in the example provided, corresponds or reflects change data 121 received from the user device 10) to the computing device 12, to cause the corresponding IGDS 100 to update the DUE 125 as rendered on that device. The computing device 12 may also use the remotely generated change data 171 to update with the local data structure representation 111 of that computing device 12. The program interface 102 of the computing device 12 can receive the update from the network computing system 150, and the rendering engine 120 can update the DUE 125 and the respective local copy of 111 of the computing device 12.

The reverse process can also be implemented to update the data structure representations 161 of the network computing system 150 using change data 121 communicated from the second computing device 12 (e.g., corresponding to the user of the second computing device updating the DUE 125 as rendered on the second computing device 12). In turn, the network computing system 150 can stream remotely generated change data 171 (which in the example provided, corresponds or reflects change data 121 received from the user device 12) to update the local data structure representation 111 of the DUE 125 on the first computing device 10. In this way, the DUE 125 of the first computing device 10 can be updated as a response to the user of the second computing device 12 providing user input to change the DUE 125.

To facilitate the synchronization of the data structure representations 111, 111 on the computing devices 10, 12, the network computing system 150 may implement a stream connector to merge the data streams which are exchanged between the first computing device 10 and the network computing system 150, and between the second computing device 12 and the network computing system 150. In some implementations, the stream connector can be implemented to enable each computing device 10, 12 to make changes to the network-side data representation 161, without added data replication that may otherwise be required to process the streams from each device separately.

Additionally, over time, one or both of the computing devices 10, 12 may become out-of-sync with the server-side data representation 161. In such cases, the respective computing device 10, 12 can redownload the active workspace files 163, to restart its maintenance of the data structure representation of the DUE 125 that is rendered and edited on that device.

Further, as described by other examples, the layout engine 160 can execute selected layout logic 162 to implement a predefined layout configuration amongst a grouping of objects (e.g., parent child object grouping). In this way, the layout engine 160 can execute a select layout logic 162 for a linked object grouping in order to implement and maintain a configuration in which a parent object is resized maintain a dimensional relationship with respect to one or more of its child objects. For example, the layout configuration can provide for a parent object to be set to a dimension that borders, or is slightly larger than the combined or overall dimensions of its child objects (e.g., “hug layout logic”). When a user provides input that changes the combined or overall dimension of the child object, the parent object is resized accordingly, to maintain the set dimensional relationship between the parent object and its child objects.

When layout engine 160 is implemented in a collaborative environment, the IGDS can facilitate users of different roles and/or skill-level in collaborating on a given DUE 125. For example, the rendering engine 120 can execute the layout logic 160 to enable a user that is highly-skilled and/or whom has primary control (“primary user”) of the DUE 125, to select to have a parent/child grouping of objects associated with the layout configuration or behavior. A second user who collaborates on the DUE 125 may then enter input that manipulates the child object, without having to perform the additional task of resizing the parent object. Through use of layout engine 160, the primary user can control size and position parameters relating to an object grouping, so as to better control other users (e.g., less-skilled or secondary users) from manipulating the object grouping in a manner that is undesired. In this way, the layout engine 160 enables primary or skilled users to select layout logic 162 to implement quality control in the design of select object groupings.

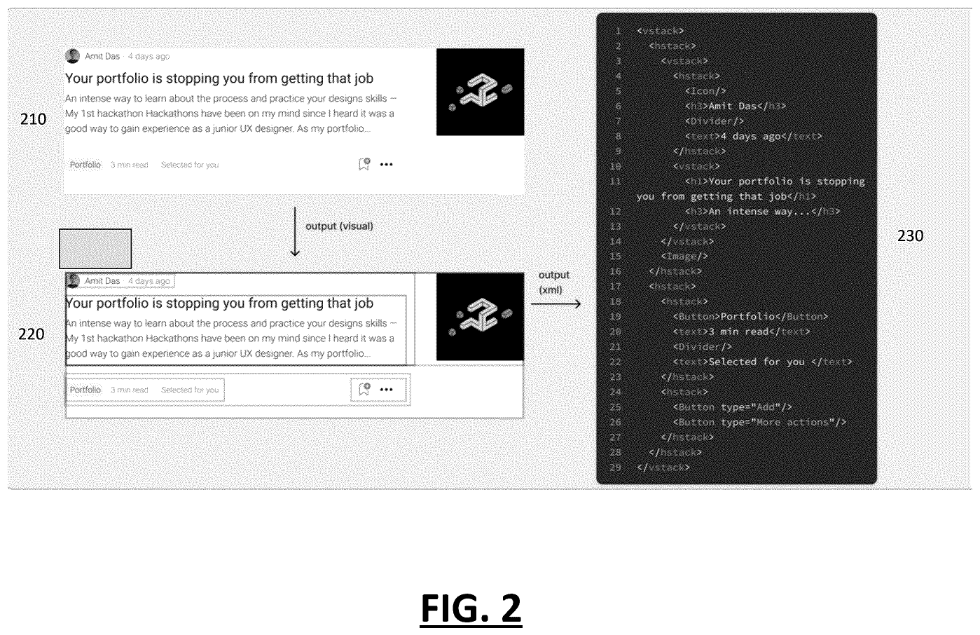

FIG. 2 illustrates an example flat design converted into a responsive design, including an example XML output, through an auto layout inference engine. The example flat design 210 shows several design elements, or nodes, including images, text, and interactable buttons. The auto layout inference engine takes the nodes from the flat design 210 and attempts to obtain a structure that inserts vertical stacks and horizontal stacks as the ancestors of the nodes, such that the positions and sizes of the nodes remain unchanged.

The responsive design 220 is an example output from the auto layout inference engine. In this example, bounding rectangles have been added to visually indicate the newly added horizontal and vertical stacks in the responsive design 220 and which nodes belong as child nodes of those stacks. For example, the “Portfolio,” “3 min read,” divider, and “Selected for you” nodes have been placed together under a single horizontal stack. That horizontal stack is also shown to be the child node of another horizontal stack with a horizontal stack including an “add” button and a “more actions” button.

The XML representation 230 of the new responsive design 220 shows sample code that includes each of the newly added horizontal stack <hstack> and vertical stack <vstack> nodes that enable auto layout features to function.

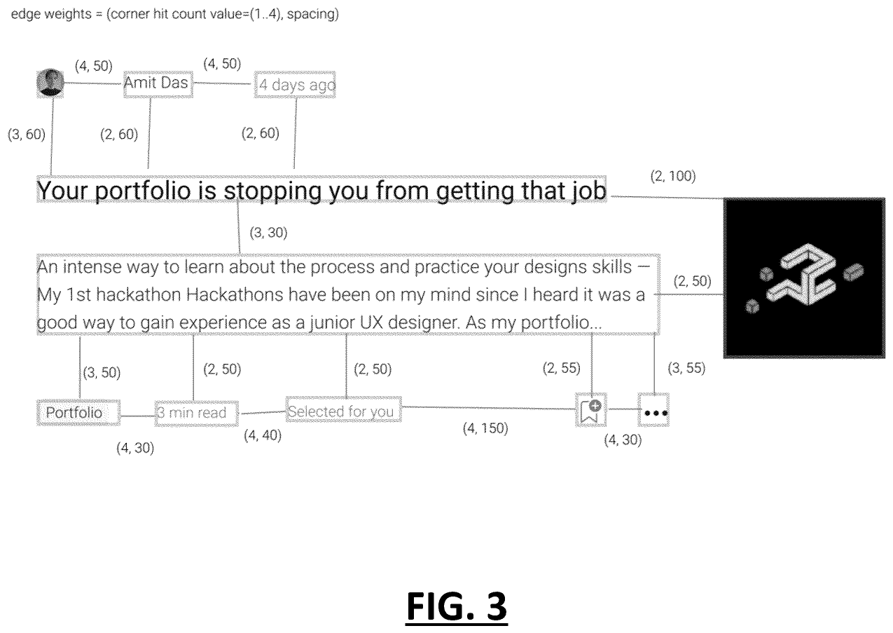

FIG. 3 illustrates an example visual graph representation of a design with nodes and edge weights shown. The example design shows several design elements, or nodes, including images, text, and interactable buttons. Each node in the design is associated with a rectangular bounding box that defines the sides of the node for the purpose of determining alignments and distances between nodes.

In some aspects, the auto layout inference engine creates a densely connected graph where the vertices are the nodes of the design and the edges connecting the nodes have edge weights that each include (1) an alignment hit count and (2) a distance measurement between the adjacent nodes. The alignment hit count between adjacent nodes in the graph is determined by (1) casting rays from each corner of the adjacent nodes in both X and Y directions (top, down, left, right), and (2) counting the number of times a ray from one node intersects the other node. The distance measurement between the adjacent nodes is the number of pixels between the closest sides of the adjacent nodes. In cases where one node is wholly inside another node, only the outer node is added to the graph, and the inner node can be considered as part of the outer node. In cases where multiple nodes overlap, the auto layout inference engine can combine the overlapping nodes into a single node with a bounding box that encompasses the overlapping nodes.

As shown in FIG. 3, the edge weights are represented as tuples of (alignment hit count, spacing in pixels) along each edge between nodes. For example, the “Portfolio” text node in the bottom left corner aligns along three corners with the adjacent text block above it, and the two adjacent nodes are measured at a distance of 50 pixels. The “Portfolio” text node also aligns along four corners with the adjacent text block “3 min read” to the right, and the two adjacent nodes are measured at a distance of 30 pixels.

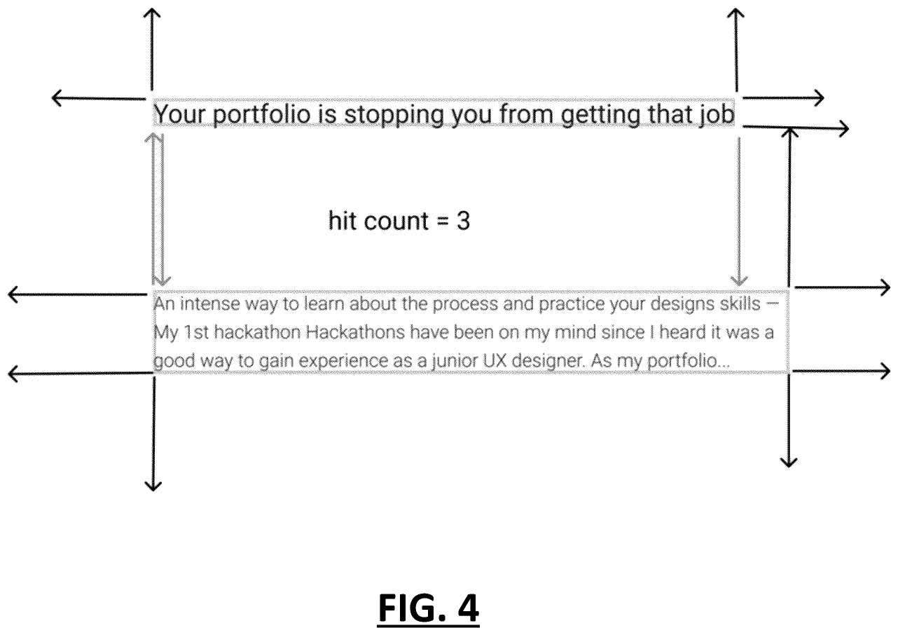

FIG. 4 illustrates an example of ray casting to determine an alignment hit count between nodes in a design. FIG. 4 shows a pair of adjacent text nodes with rectangular bounding boxes. To determine the alignment hit count between these two nodes, rays are cast from each corner of each node in both X and Y directions (top, down, left, right). As shown, from the top node with the text “Your portfolio is stopping you from getting that job,” the rays from the top left and top right corners do not intersect the bottom text node. The rays cast downwards from the bottom corners do intersect with the bottom node, which increments the hit count to 2. From the bottom node, rays cast downwards and to the sides do not intersect the top node. Since the bottom node stretches farther to the right than the top node, a ray from the top right corner of the bottom node does not intersect the top node. However, a ray from the top left corner does, further incrementing the hit count to a total of 3. If two nodes are perfectly aligned, either horizontally or vertically, the maximum hit count is 4.

In some aspects, the system may consider special cases regarding the alignment of neighboring nodes when setting the alignment hit count. For example, if two neighboring nodes are center aligned, the ray casting method returns an alignment hit count of 2. However, center aligned nodes are often designed to be kept together. Thus, the system can consider a pair of center aligned nodes to be equivalent to an alignment hit count of 4.

### Methodology

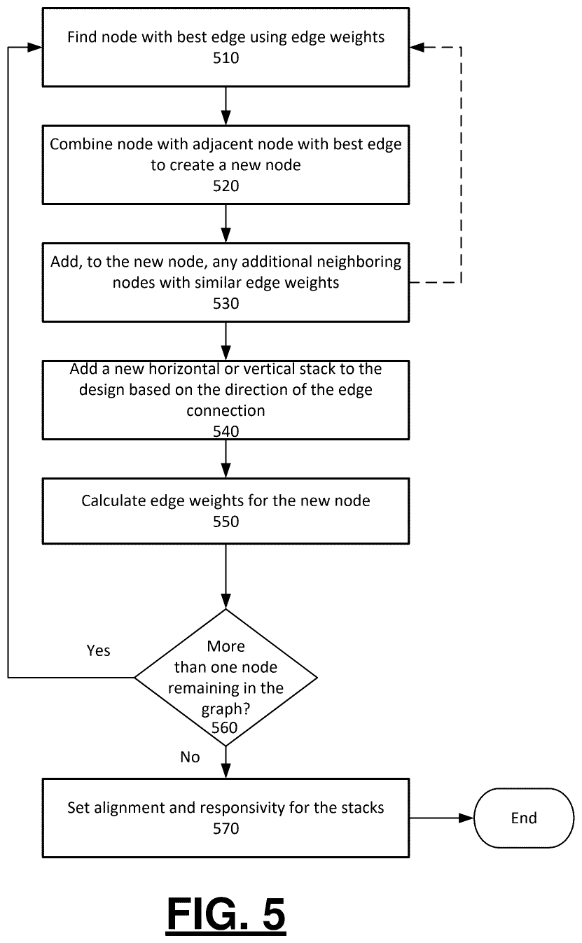

FIG. 5 is an example flow chart of a method of reducing a graph of design element nodes as part of converting a flat design to a responsive design through an auto layout inference engine. As used herein, the “system” can refer to the auto layout inference engine, which may be the auto layout component 165 of FIG. 1A.

Once the graph of design element nodes has been constructed, the auto layout inference engine iteratively reduces the graph until only one node remains. First, the system finds the node in the graph with the “best” or “optimal” edge by applying a set of criteria to the edge weights (510). In some examples, the criteria for a “best” or “optimal” edge includes meeting a predetermined minimum alignment hit count and a least distance measurement between the connected nodes. Accordingly, the auto layout inference engine iterates through edges of the nodes in order of node size, starting at a pass with a minimum alignment hit count of 4, which is the maximum possible value. Among edges with a hit count of 4, the system selects the edge with the least distance measurement as the best edge. CA If no edges remain with an alignment hit count of 4, the system can reduce the minimum alignment hit count to 3, then 2 until a single node remains in the graph.

Once a best edge is determined, the system combines the nodes connected by the edge to create a new node in the graph (520). In some examples, the system applies further criteria to determine whether to create the new node. One criterion is whether the bounding box of the new node overlaps with any other nodes in the design. If the system determines that the bounding box containing the pair of nodes connected by the edge would overlap with other nodes, the system rejects the pairing and searches the graph for the next best pairing instead according to the set of criteria.

In some aspects, the system can search for additional nodes to combine into the new node. The system searches neighboring nodes in the graph, both horizontally and vertically, and if one or more neighboring nodes are found with the same alignment hit count and a similar distance in pixels as the distance between the first pair of adjacent nodes, the neighboring node(s) are added to the new node (530). In some examples, the similar distance includes any edge weight with the exact number of pixels of distance plus or minus a predetermined tolerance value (e.g., 2-5 pixels).

During the process of adding additional nodes, the system may determine that some set of the additional nodes meets the set of criteria better than the original pair of adjacent nodes. In such a case, the system can either restart the loop with the optimal edge between the additional nodes as the starting point or group the additional nodes into one or more new nodes in an alternative manner. One such alternative manner is used when the system detects that a pivot rule should be applied to optimize for groups of repeating content.

When searching for additional nodes to add to the new node, the system searches in the direction perpendicular to the direction of the edge to determine whether there are additional pairs of nodes which line up with the original pair of nodes. To determine whether to apply the pivot rule, the system determines a signature from the properties of each node (e.g., the type of node, its size, etc.). If the pairs of nodes in the perpendicular direction each have matching signatures, the system can apply the pivot rule to favor pairing the nodes in the perpendicular direction instead of the original direction of the edge. For example, if a 2×4 (horizontal×vertical) matrix of nodes has its highest alignment hit count in the horizontal direction, the system checks the other three horizontal pairings before committing to combining the two nodes horizontally. If each pair has the same signature, rather than creating one horizontal pair four times, the pivot rule has the system create two vertical stacks of four nodes.

The auto layout inference engine adds a new horizontal or vertical stack to the design based on the direction of the edge connection (540). The new stack is set as a parent node to the adjacent nodes and any additional neighboring nodes that were found in the previous step. The new stack can be added to a code representation (e.g., an XML representation) of the design. Any of the nodes added as child nodes to the new stack are then removed from the graph.

The auto layout inference engine calculates edge weights for the newly added horizontal or vertical stack node (550). For example, the system inserts the new stack node in place of one of the removed child nodes then calculates, for each of the nodes adjacent to the removed child nodes, an alignment hit count and pixel distance between the new stack node and each node.

In some aspects, the system iteratively performs the above operations until only one node remains in the graph (560). If more than one node remains in the graph and the system is unable to continue finding the next best edge, the system can abort the process and return an error message to the user. In the case of an abort, the original design remains unmodified.

If only one node remains, then that means each of the original nodes and the newly added horizontal and vertical stacks have been added as child nodes of the one remaining node, forming a hierarchy used by the design system's auto layout feature. Upon determining that only one node remains in the graph, the system sets the alignment and responsivity for each of the created stacks (570). The system can run an alignment detection operation on the nodes to determine which alignment layout most closely matches the positioning of the original nodes in the flat design. For example, the alignment of a vertical stack may be set to centered and top aligned if that most closely matches the original design. Additionally, the responsivity setting can be set to one of a fill, fixed, or hug in both dimensions based on which responsivity most closely matches the original nodes in the flat design. Upon successful completion of setting the alignment and responsivity for the newly added stacks, the system can replace the original flat design structure with the newly created responsive structure.

### Network Computer System

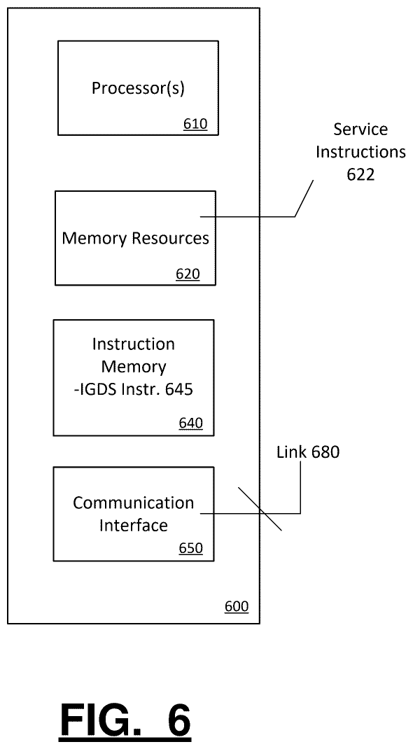

FIG. 6 illustrates a computer system on which one or more embodiments can be implemented. A computer system 600 can be implemented on, for example, a server or combination of servers. For example, the computer system 600 may be implemented as the network computing system 150 of FIG. 1A through FIG. 1C.

In one implementation, the computer system 600 includes processing resources 610, memory resources 620 (e.g., read-only memory (ROM) or random-access memory (RAM)), one or more instruction memory resources 640, and a communication interface 650. The computer system 600 includes at least one processor 610 for processing information stored with the memory resources 620, such as provided by a random-access memory (RAM) or other dynamic storage device, for storing information and instructions which are executable by the processor 610. The memory resources 620 may also be used to store temporary variables or other intermediate information during execution of instructions to be executed by the processor 610.

The communication interface 650 enables the computer system 600 to communicate with one or more user computing devices, over one or more networks (e.g., cellular network) through use of the network link 680 (wireless or a wire). Using the network link 680, the computer system 600 can communicate with one or more computing devices, specialized devices and modules, and/or one or more servers.

In examples, the processor 610 may execute service instructions 622, stored with the memory resources 620, in order to enable the network computing system to implement the network service 172 and operate as the network computing system 170 in examples such as described with FIG. 1A through FIG. 1C.

The computer system 600 may also include additional memory resources (“instruction memory 640”) for storing executable instruction sets (“IGDS instructions 645”) which are embedded with webpages and other web resources, to enable user computing devices to implement functionality such as described with the IGDS 100.

As such, examples described herein are related to the use of the computer system 600 for implementing the techniques described herein. According to an aspect, techniques are performed by the computer system 600 in response to the processor 610 executing one or more sequences of one or more instructions contained in the memory 620. Such instructions may be read into the memory 620 from another machine-readable medium. Execution of the sequences of instructions contained in the memory 620 causes the processor 610 to perform the process steps described herein. In alternative implementations, hard-wired circuitry may be used in place of or in combination with software instructions to implement examples described herein. Thus, the examples described are not limited to any specific combination of hardware circuitry and software.

### User Computing Device

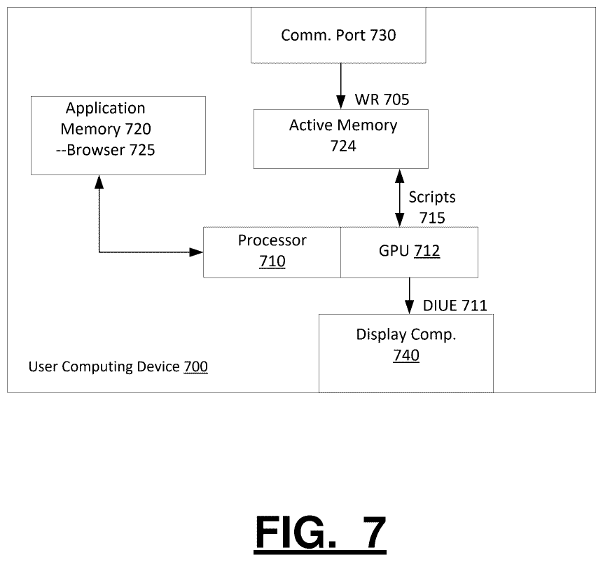

FIG. 7 illustrates a user computing device for use with one or more examples, as described. In examples, a user computing device 700 can correspond to, for example, a workstation, a desktop computer, a laptop or other computer system having graphics processing capabilities that are suitable for enabling renderings of design interfaces and graphic design work. In variations, the user computing device 700 can correspond to a mobile computing device, such as a smartphone, tablet computer, laptop computer, VR or AR headset device, and the like.

In examples, the computing device 700 includes a central or main processor 710, a graphics processing unit 712, memory resources 720, and one or more communication ports 730. The computing device 700 can use the main processor 710 and the memory resources 720 to store and launch a browser 725 or other web-based application. A user can operate the browser 725 to access a network site of the network service 152, using the communication port 730, where one or more web pages or other resources 705 for the network service 152 (see FIG. 1A through FIG. 1C) can be downloaded. The web resources 705 can be stored in the active memory 724 (cache).

As described by various examples, the processor 710 can detect and execute scripts and other logic which are embedded in the web resource in order to implement the IGDS 100 (see FIG. 1A through FIG. 1C). In some of the examples, some of the scripts 715 which are embedded with the web resources 705 can include GPU accelerated logic that is executed directly by the GPU 712. The main processor 710 and the GPU can combine to render a design interface under edit (“DIUE 711”) on a display component 740. The rendered design interface can include web content from the browser 725, as well as design interface content and functional elements generated by scripts and other logic embedded with the web resource 705. By including scripts 715 that are directly executable on the GPU 712, the logic embedded with the web resource 705 can better execute the IGDS 100, as described with various examples.

### Example Clauses

CLAUSE 1. A computer system comprising: one or more processors; and one or more memory resources storing instructions that, when executed by the one or more processors, cause the computer system to perform operations comprising: building a graph of nodes representing design elements within a design interface having a flat structure, wherein edge weights between adjacent nodes in the graph of nodes include (1) an alignment hit count and (2) a distance measurement between the adjacent nodes; iteratively merging the nodes in the graph of nodes based on the edge weights; and converting, within the design interface, the flat structure into a responsive structure, with positions and sizes of the design elements unchanged, based on merging the nodes.

CLAUSE 2. The computer system of clause 1, further comprising: determining the alignment hit count between adjacent nodes in the graph by (1) casting rays from each corner of the adjacent nodes in both X and Y directions, and (2) counting the number of times a ray from one node intersects the other node.

CLAUSE 3. The computer system of clause 1 or 2, wherein iteratively merging the nodes in the graph of nodes based on the edge weights comprises: (a) selecting a pair of adjacent nodes with a predetermined minimum alignment hit count and a least distance measurement between them; (b) combining the pair of adjacent nodes into a new node in the graph of nodes; (c) removing the pair of adjacent nodes from the graph of nodes; and (d) repeating (a)-(c) until a single node remains.

CLAUSE 4. The computer system of any of clauses 1-3, wherein the flat structure is converted into the responsive structure by inserting vertical stacks and/or horizontal stacks as ancestors of the design elements upon combining the pair of adjacent nodes into the new node.

CLAUSE 5. The computer system of any of clauses 1-4, further comprising: setting alignments for each of the vertical stacks and horizontal stacks.

CLAUSE 6. The computer system of any of clauses 1-5, further comprising: setting responsivities for each of the vertical stacks and horizontal stacks.

CLAUSE 7. The computer system of any of clauses 1-6, wherein the distance measurement between the adjacent nodes is a number of pixels between the closest sides of the adjacent nodes.

CLAUSE 8. A computer-implemented method comprising: building a graph of nodes representing design elements within a design interface having a flat structure, wherein edge weights between adjacent nodes in the graph of nodes include (1) an alignment hit count and (2) a distance measurement between the adjacent nodes; iteratively merging the nodes in the graph of nodes based on the edge weights; and converting, within the design interface, the flat structure into a responsive structure, with positions and sizes of the design elements unchanged, based on merging the nodes.

CLAUSE 9. The method of clause 8, further comprising: determining the alignment hit count between adjacent nodes in the graph by (1) casting rays from each corner of the adjacent nodes in both X and Y directions, and (2) counting the number of times a ray from one node intersects the other node.

CLAUSE 10. The method of clause 8 or 9, wherein iteratively merging the nodes in the graph of nodes based on the edge weights comprises: (a) selecting a pair of adjacent nodes with a predetermined minimum alignment hit count and a least distance measurement between them; (b) combining the pair of adjacent nodes into a new node in the graph of nodes; (c) removing the pair of adjacent nodes from the graph of nodes; and (d) repeating (a)-(c) until a single node remains.

CLAUSE 11. The method of any of clauses 8-10, wherein the flat structure is converted into the responsive structure by inserting vertical stacks and/or horizontal stacks as ancestors of the design elements upon combining the pair of adjacent nodes into the new node.

CLAUSE 12. The method of any of clauses 8-11, further comprising: setting alignments for each of the vertical stacks and horizontal stacks.

CLAUSE 13. The method of any of clauses 8-12, further comprising: setting responsivities for each of the vertical stacks and horizontal stacks.

CLAUSE 14. The method of any of clauses 8-13, wherein the distance measurement between the adjacent nodes is a number of pixels between the closest sides of the adjacent nodes.

CLAUSE 15. A non-transitory computer-readable medium that stores instructions, executable by one or more processors, to cause the one or more processors to perform operations comprising: building a graph of nodes representing design elements within a design interface having a flat structure, wherein edge weights between adjacent nodes in the graph of nodes include (1) an alignment hit count and (2) a distance measurement between the adjacent nodes; iteratively merging the nodes in the graph of nodes based on the edge weights; and converting, within the design interface, the flat structure into a responsive structure, with positions and sizes of the design elements unchanged, based on merging the nodes.

CLAUSE 16. The non-transitory computer-readable medium of clause 15, further comprising: determining the alignment hit count between adjacent nodes in the graph by (1) casting rays from each corner of the adjacent nodes in both X and Y directions, and (2) counting the number of times a ray from one node intersects the other node.

CLAUSE 17. The non-transitory computer-readable medium of clause 15 or 16, wherein iteratively merging the nodes in the graph of nodes based on the edge weights comprises: (a) selecting a pair of adjacent nodes with a predetermined minimum alignment hit count and a least distance measurement between them; (b) combining the pair of adjacent nodes into a new node in the graph of nodes; (c) removing the pair of adjacent nodes from the graph of nodes; and (d) repeating (a)-(c) until a single node remains.

CLAUSE 18. The non-transitory computer-readable medium of any of clauses 15-17, wherein the flat structure is converted into the responsive structure by inserting vertical stacks and/or horizontal stacks as ancestors of the design elements upon combining the pair of adjacent nodes into the new node.

CLAUSE 19. The non-transitory computer-readable medium of any of clauses 15-18, further comprising: setting alignments for each of the vertical stacks and horizontal stacks.

CLAUSE 20. The non-transitory computer-readable medium of any of clauses 15-19, further comprising: setting responsivities for each of the vertical stacks and horizontal stacks.

### Conclusion

Although examples are described in detail herein with reference to the accompanying drawings, it is to be understood that the concepts are not limited to those precise examples. Accordingly, it is intended that the scope of the concepts be defined by the following claims and their equivalents. Furthermore, it is contemplated that a particular feature described either individually or as part of an example can be combined with other individually described features, or parts of other examples, even if the other features and examples make no mentioned of the particular feature. Thus, the absence of describing combinations should not preclude having rights to such combinations.

What is claimed is:

1. A computer system comprising:
one or more processors; and
one or more memory resources storing instructions that, when executed by the one or more processors, cause the computer system to perform operations comprising:
building a graph of nodes representing design elements within a design interface having a flat structure, wherein edge weights between adjacent nodes in the graph of nodes include (1) an alignment hit count and (2) a distance measurement between the adjacent nodes;
iteratively merging the nodes in the graph of nodes based on the edge weights; and
converting, within the design interface, the flat structure into a responsive structure, with positions and sizes of the design elements unchanged, based on merging the nodes.

2. The computer system of claim 1, further comprising:
determining the alignment hit count between adjacent nodes in the graph by (1) casting rays from each corner of the adjacent nodes in both X and Y directions, and (2) counting the number of times a ray from one node intersects the other node.

3. The computer system of claim 1, wherein iteratively merging the nodes in the graph of nodes based on the edge weights comprises:
(a) selecting a pair of adjacent nodes with a predetermined minimum alignment hit count and a least distance measurement between them;
(b) combining the pair of adjacent nodes into a new node in the graph of nodes;
(c) removing the pair of adjacent nodes from the graph of nodes; and
(d) repeating (a)-(c) until a single node remains.

4. The computer system of claim 3, wherein the flat structure is converted into the responsive structure by inserting vertical stacks and/or horizontal stacks as ancestors of the design elements upon combining the pair of adjacent nodes into the new node.

5. The computer system of claim 4, further comprising:
setting alignments for each of the vertical stacks and horizontal stacks.

6. The computer system of claim 4, further comprising:
setting responsivities for each of the vertical stacks and horizontal stacks.

7. The computer system of claim 1, wherein the distance measurement between the adjacent nodes is a number of pixels between the closest sides of the adjacent nodes.

8. A computer-implemented method comprising:
building a graph of nodes representing design elements within a design interface having a flat structure, wherein edge weights between adjacent nodes in the graph of nodes include (1) an alignment hit count and (2) a distance measurement between the adjacent nodes;
iteratively merging the nodes in the graph of nodes based on the edge weights; and
converting, within the design interface, the flat structure into a responsive structure, with positions and sizes of the design elements unchanged, based on merging the nodes.

9. The method of claim 8, further comprising:
determining the alignment hit count between adjacent nodes in the graph by (1) casting rays from each corner of the adjacent nodes in both X and Y directions, and (2) counting the number of times a ray from one node intersects the other node.

10. The method of claim 8, wherein iteratively merging the nodes in the graph of nodes based on the edge weights comprises:
(a) selecting a pair of adjacent nodes with a predetermined minimum alignment hit count and a least distance measurement between them;
(b) combining the pair of adjacent nodes into a new node in the graph of nodes;
(c) removing the pair of adjacent nodes from the graph of nodes; and
(d) repeating (a)-(c) until a single node remains.

11. The method of claim 10, wherein the flat structure is converted into the responsive structure by inserting vertical stacks and/or horizontal stacks as ancestors of the design elements upon combining the pair of adjacent nodes into the new node.

12. The method of claim 11, further comprising:
setting alignments for each of the vertical stacks and horizontal stacks.

13. The method of claim 11, further comprising:
setting responsivities for each of the vertical stacks and horizontal stacks.

14. The method of claim 8, wherein the distance measurement between the adjacent nodes is a number of pixels between the closest sides of the adjacent nodes.

15. A non-transitory computer-readable medium that stores instructions, executable by one or more processors, to cause the one or more processors to perform operations comprising:
building a graph of nodes representing design elements within a design interface having a flat structure, wherein edge weights between adjacent nodes in the graph of nodes include (1) an alignment hit count and (2) a distance measurement between the adjacent nodes;
iteratively merging the nodes in the graph of nodes based on the edge weights; and
converting, within the design interface, the flat structure into a responsive structure, with positions and sizes of the design elements unchanged, based on merging the nodes.

16. The non-transitory computer-readable medium of claim 15, further comprising:
determining the alignment hit count between adjacent nodes in the graph by (1) casting rays from each corner of the adjacent nodes in both X and Y directions, and (2) counting the number of times a ray from one node intersects the other node.

17. The non-transitory computer-readable medium of claim 15, wherein iteratively merging the nodes in the graph of nodes based on the edge weights comprises:
(a) selecting a pair of adjacent nodes with a predetermined minimum alignment hit count and a least distance measurement between them;
(b) combining the pair of adjacent nodes into a new node in the graph of nodes;
(c) removing the pair of adjacent nodes from the graph of nodes; and
(d) repeating (a)-(c) until a single node remains.

18. The non-transitory computer-readable medium of claim 17, wherein the flat structure is converted into the responsive structure by inserting vertical stacks and/or horizontal stacks as ancestors of the design elements upon combining the pair of adjacent nodes into the new node.

19. The non-transitory computer-readable medium of claim 18, further comprising:
setting alignments for each of the vertical stacks and horizontal stacks.

20. The non-transitory computer-readable medium of claim 18, further comprising:
setting responsivities for each of the vertical stacks and horizontal stacks.
